(19) United States
(12) Patent Application Publication
(10) Pub. No.: US 2019/0027373 A1
(43) Pub. Date: Jan. 24, 2019

(54) Method For Selectively Etching Silicon Oxide Film

(71) Applicant: TES CO., LTD, Yongin (KR)

(72) Inventors: Bong-Soo Kwon, Yongin (KR); Tae-Yong Sim, Yongin (KR)

(73) Assignee: TES CO., LTD

(21) Appl. No.: 16/141,162

(22) Filed: Sep. 25, 2018

Related U.S. Application Data
(63) Continuation of application No. PCT/KR2017/003671, filed on Apr. 4, 2017.

(30) Foreign Application Priority Data
Apr. 5, 2016 (KR) 10-2016-0041527
Apr. 5, 2016 (KR) 10-2016-0041528

(51) Int. Cl. H01L 21/311; H01L 21/3213; H01L 21/02

(52) U.S. Cl. CPC H01L 21/31116; H01L 21/02164; H01L 21/3213

(57) ABSTRACT

The present invention relates to a method for selectively etching a silicon oxide film by using a low-temperature process in a semiconductor manufacturing process and, more specifically, the method comprises the steps of: putting, into a reactor, a substrate having a silicon oxide film and a silicon nitride film formed thereon; setting process conditions including a process temperature having a range of 0° C. to 30° C. below zero; and supplying process gas into the reactor under the process conditions so as to selectively etch the silicon oxide film with respect to the silicon nitride film.

### CROSS-REFERENCE TO RELATED APPLICATIONS

This application is a continuation application of International Application No. PCT/KR2017/003671 filed on Apr. 4, 2017, which claims priority to Korean Application No. 10-2016-0041527 filed on Apr. 5, 2016 and Korean Application No. 10-2016-0041528 filed on Apr. 5, 2016. The applications are incorporated herein by reference.

### TECHNICAL FIELD

The present invention relates to a selective etching method of a silicon oxide film using a low temperature process in a semiconductor fabrication process and, more particularly, to a selective etching method of a silicon oxide film using a low temperature process for acquisition of high etch selectivity.

### BACKGROUND ART

A semiconductor fabrication process has applied various processes of selectively removing a silicon oxide film while maintaining a silicon nitride film using different etching characteristics of a silicon oxide (SiO₂) film and a silicon nitride (Si₃N₄) film.

An example of a memory device manufacturing process includes a process of forming a lower electrode of a cylindrical capacitor and, then, removing a mold oxide film or a process of selectively removing a silicon oxide film using a silicon nitride film as an etching barrier when an air gap is formed for insulation between metallic wirings.

To this end, conventionally, a wet or plasma etching method is used, but the wet etching method is not appropriate to embody a fine pattern due to a problem in terms of pattern collapses while having high etch selectivity between thin films, and the plasma etching method is capable of embodying a fine pattern, but has a problem in that charging damage occurs at a lower film due to charged particles and has a difficulty in selectively removing a thin film due to low etch selectivity between thin films.

Accordingly, recently, gas phase etching (GPE) of vaporizing an etchant, etc. that are used in conventional wet etching, injecting the etchant, etc. into a reactor and, then, removing a thin film via chemical reaction has been introduced and applied.

In this case, to selectively etch a silicon oxide film, hydrogen fluoride (HF) gas is mainly used and, in this regard, ammonia (NH₃) containing hydrogen (H) is also used to adjust etching characteristics of the silicon oxide film.

However, in accordance with recent trends, these methods are still insufficient to correspond to high etch selectivity of a silicon oxide film and a silicon nitride film, which is desperately needed along with recent miniaturization of patterns.

### SUMMARY

An object of the present invention devised to solve the problem lies in a selective etching method of a silicon oxide film, for originally preventing a non-volatile reaction product from being generated and overcoming a problem in terms of non-uniform process temperature due to a thermal process.

In addition, another object of the present invention provides a selective etching method of a silicon oxide film, for remarkably enhancing etch selectivity.

The object of the present invention can be achieved by providing a selective etching method of a silicon oxide film, including transferring a substrate with a silicon oxide film and a silicon nitride film formed thereon into a reactor, setting a process condition including process temperature of the substrate in the range of 0° C. to 30° C. below zero, and supplying process gas to the reactor under the process condition to selectively etch the silicon oxide film with respect to the silicon nitride film.

Process pressure in the reactor is in the range of 30 to 200 Torr.

Process pressure in the reactor may be maintained at 50 to 150 Torr, and hydrogen fluoride (HF) gas and IPA gas may be used as the process gas.

A flow rate ratio of the hydrogen fluoride (HF) gas and the IPA gas may be equal to or greater than 5:1 or may be equal to or greater than 10:1.

In another aspect of the present invention, provided herein is a selective etching method of a silicon oxide film, including transferring a substrate with a silicon oxide film and a silicon nitride film formed thereon into a reactor, setting a process condition including process gas in the reactor, process pressure of the substrate, and process temperature for selectively removing a silicon oxide film with respect to the silicon nitride film, and supplying only hydrogen fluoride (HF) as the process gas with a predetermined flow rate or greater onto the substrate to selectively etch the silicon oxide film with respect to the silicon nitride film.

The flow rate of the hydrogen fluoride (HF) may be 2000 to 3000 sccm.

The process pressure in the reactor may be maintained in the range of 50 to 150 Torr and the process temperature may be maintained in the range of 10° C. below zero to 30° C. below zero.

In the selective etching method of a silicon oxide film according to the present invention, an etching process may be performed at high pressure and a low temperature condition of temperature below zero differently from the prior art, and, thus, etch selectivity of a silicon oxide film may be advantageously and remarkably enhanced.

The selective etching method of a silicon oxide film according to the present invention may use a dry etching method of injecting hydrogen fluoride (HF) and alcohol in a gas phase and, thus, a non-volatility reaction product may be advantageously and originally prevented from being generated and a problem in terms of non-uniform process temperature due to a thermal process may be advantageously overcome.

### BRIEF DESCRIPTION OF DRAWINGS

FIG. 1 is a schematic diagram of a silicon oxide film etching apparatus using a low temperature process according to the present invention.

FIG. 2 is a process flow chart of a selective etching method of a silicon oxide film using a low temperature process according to the present invention.

FIG. 3 is a graph showing an etching amount and etch selectivity depending on process pressure in a selective etching method of a silicon oxide film using a low temperature process according to the present invention.

FIG. 4 is a graph showing an etching amount and etch selectivity depending on substrate temperature in a selective etching method of a silicon oxide film using a low temperature process according to the present invention.

FIG. 5 is a graph for evaluation on a tendency of an etching amount and etch selectivity when substrate temperature is maintained at further low temperature in a selective etching method of a silicon oxide film using a low temperature process according to the present invention.

FIG. 6 is a graph showing an etching amount and etch selectivity depending on a flow rate of IAP in a selective etching method of a silicon oxide film using a low temperature process according to the present invention.

FIG. 7 is a graph showing an etching amount depending on an etching time in a selective etching method of a silicon oxide film using a low temperature process according to another embodiment of the present invention.

FIG. 8 is a graph showing an etching amount depending on a flow rate of hydrogen fluoride (HF) gas in a selective etching method of a silicon oxide film using a low temperature process according to another embodiment of the present invention.

### DETAILED DESCRIPTION

Reference will now be made in detail to the exemplary embodiments of the present invention, examples of which are illustrated in the accompanying drawings.

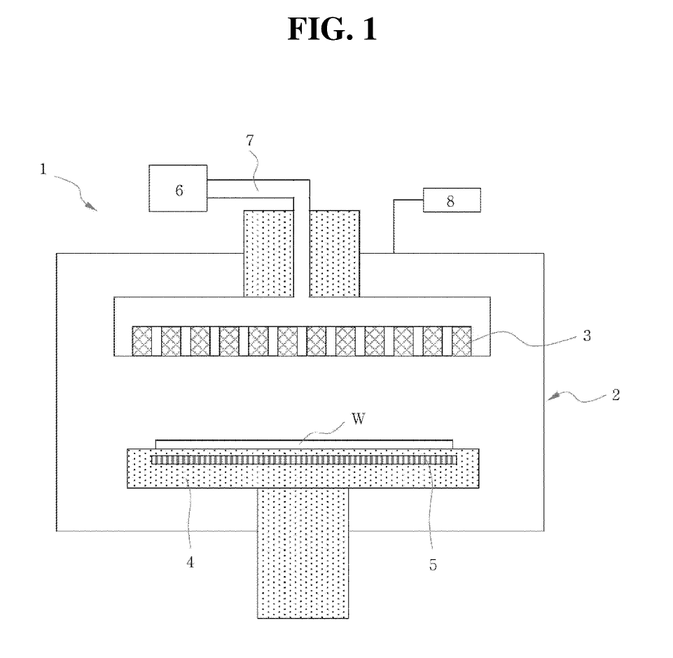

FIG. 1 is a schematic diagram of a silicon oxide film etching apparatus using a low temperature process according to the present invention.

A silicon oxide film etching apparatus 1 according to the present invention may include a reactor 2, a shower head 3, a substrate support 4, a temperature adjuster 5, a gas supplying unit 6, a gas supplying line 7, and a controller 8 for controlling the etching apparatus.

The shower head 3 may be disposed at an upper portion of an internal portion of the reactor 2 and may inject process gas supplied through the gas supplying line 7 connected to the external gas supplying unit 6, into a reactor 2.

The reactor 2 may include the substrate support 4 that is disposed at a lower portion of the internal portion of the reactor 2 to face the shower head 3 and accommodates and supports a substrate W transferred into the reactor 2.

The substrate support 4 may include the temperature adjuster 5 for adjusting temperature of the substrate W to 0° C. or less from room temperature.

When the substrate W is mounted to the substrate support 4, pressure inside the reactor 2 may be adjusted by an external vacuum system (not shown), temperature of a substrate may be adjusted by the temperature adjuster 5, and process gas may be supplied to etch the silicon oxide film on the substrate via a chemical reaction.

In this case, the controller 8 may control related members for an etching process, such as the gas supplying unit 6, the temperature adjuster 5, and the vacuum system, and may perform a process.

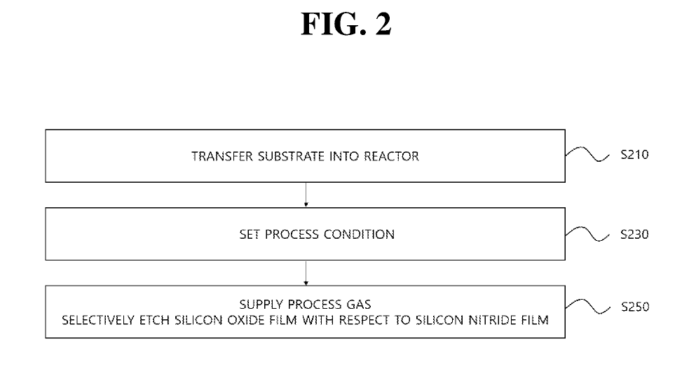

FIG. 2 is a process flow chart of a selective etching method of a silicon oxide film using a low temperature process according to the present invention.

Hereinafter, for convenience of description, the selective etching method of the silicon oxide film according to various embodiments of the present disclosure is described in an operation sequence with respect to FIG. 2 above.

### First Embodiment

First, in the selective etching method of the silicon oxide film according to an embodiment of the present disclosure, when the substrate W with a silicon oxide film and a silicon nitride film formed thereon is mounted to the substrate support 4 inside the reactor 2 (S210) and accommodated on the substrate support 4, a process condition including at least one of process pressure and process temperature inside the reactor 2 may be set (S230).

Accordingly, process pressure inside the reactor 2 may be in the range of 30 to 200 Torr, in more detail, 50 to 150 Torr in conjunction with a desired process target value and, according to the present invention, the size of the reactor 2 may be reduced compared with the prior art to rapidly and smoothly adjust process pressure of high temperature and a difference between pressures for transferring the substrate W to and out of the reactor 2.

Simultaneously with the adjustment of process pressure or after and before the adjustment of process pressure, temperature of the substrate W may be adjusted.

Accordingly, the temperature adjuster 5 of the substrate support 4 may maintain temperature of the substrate W at 0° C. to 30° C. below zero, in more detail, 10° C. below zero to 30° C. below zero, which is appropriate for a selective etching process of a silicon oxide film according to the present invention in conjunction with an external chiller (not shown).

When process pressure and substrate temperature inside the reactor 2 are adjusted, process gas may be injected into the reactor 2 to selectively etch the silicon oxide film with respect to the silicon nitride film (S250).

The process gas may use any one of hydrogen fluoride (HF) or gas obtained by diluting HF such as diluted HF (DHF) or buffered oxide etch (BOE) and may use any one of known alcohol gases along with the former gas.

According to the present invention, an example in which isopropyl alcohol (IPA) (C₃H₇OH) is used as process gas along with hydrogen fluoride (HF) is described.

The HF and isopropyl alcohol (IPA) (C₃H₇OH) are present in a liquid phase at room temperature and, thus, may be vaporized using a separate gasifier (not shown) and, then, may be injected into the reactor 2 through the gas supplying unit 6, the gas supplying line 7, and the shower head 3.

In this case, helium (He), argon (Ar), or nitrogen (N₂) gas which is inert gas may also be supplied as carrier gas along with the process gas to enhance etch uniformity.

A supplying amount of the process gas may be adjusted depending on a process target value but, according to the present disclosure, for example, the HF may be supplied in the range of 1000 to 4000 standard cubic centimeter per minute (sccm) and isopropyl alcohol (IPA) (C₃H₇OH) may be supplied in the range of 1 to 300 sccm.

When the process gas is supplied, the silicon oxide film on a substrate may be selectively etched with respect to the silicon nitride film through chemical reaction using a process condition inside the reactor 2 and the process gas.

When selective etching of the silicon oxide film is completed, pressure inside the reactor 2 may be lowered to pressure appropriate for movement of the substrate W and, then, the substrate may be transferred out of the reactor 2 to complete a process.

Hereinafter, the technical features of the selective etching method of the silicon oxide film using a low temperature process according to the present disclosure are described compared with the problem of the prior art.

A conventional chemical dry etching method mainly uses hydrogen fluoride (HF) and ammonia (NH₃) as process gas and, in this case, silicon tetrafluoride (SiF₄) generated via reaction between the silicon oxide film and hydrogen fluoride (HF) according to Reaction Scheme 1 below may re-react with hydrogen fluoride (HF) and ammonia (NH₃) to generate ammonium hexafluorosilicate ((NH₄)₂SiF₆) according to Reaction Scheme 2 and 3.

SiO₂+4HF→SiF₄+2H₂O [Reaction Scheme 1]

SiO₂+4HF+4NH₃→SiF₄+2H₂O+4NH₃ [Reaction Scheme 2]

SiF₄+2HF+2NH₃→(NH₄)₂SiF₆ [Reaction Scheme 3]

Ammonium hexafluorosilicate ((NH₄)₂SiF₆) vaporizes (sublimates) at high temperature equal to or greater than about 100° C. and is removed due to low volatility and, thus, there is a problem in that the silicon oxide film is etched and, then, an internal portion of the reactor needs to be heated and processed to discharge ammonium hexafluorosilicate ((NH₄)₂SiF₆).

While an etching process proceeds, ammonium hexafluorosilicate ((NH₄)₂SiF₆) that is the reaction product forms an etching barrier on a surface of the silicon oxide film to be etched and, thus, there is a problem in that process gas is not smoothly distributed up to a surface of the silicon oxide film and, as an etching time elapses, there is a problem in that an etching amount is saturated or etching is stopped.

Even if alcohol gas is used instead of ammonia (NH₃) to prevent ammonium hexafluorosilicate ((NH₄)₂SiF₆) from being generated, etch selectivity of a silicon oxide film and a silicon nitride film is less than 10:1 and, thus, there is a problem in that the conventional method is not applicable to a recent semiconductor etching process that requires high selectivity.

On the other hand, the selective etching method of the silicon oxide film using the low temperature process according to the present invention may originally prevent a non-volatile reaction product from being generated using hydrogen fluoride (HF) and isopropyl alcohol (IPA) (C₃H₇OH) as process gas, as described above, and may also maintain high pressure and low temperature below zero compared with the prior art to remarkably enhance an etching amount and etch selectivity.

In this regard, a mechanism of etching a silicon oxide film using hydrogen fluoride (HF) and isopropyl alcohol (IPA) (C₃H₇OH) in a low temperature process condition according to the present invention is described below in an operation sequence.

First, silanol (Si—O—H) bond may be formed on a surface of the silicon oxide film due to acidity of hydrogen fluoride (HF) and, hydrogen fluoride (HF) and isopropyl alcohol (IPA) (C₃H₇OH) that adsorb onto the silicon oxide film may generate a bifluoride (HF₂⁻) ion that is a main etching component of the silicon oxide film according to Reaction Scheme 4 below.

A process in which HF₂⁻ reacts with the silanol (Si—O—H) bond on the surface of the silicon oxide film to generate H₂SiF₆ that is an intermediate product according to Reaction Scheme 5 below and to generate and discharge silicon tetrafluoride (SiF₄) in a gas phase, which is an end product, according to Reaction Scheme 6 below may proceed.

2HF+A(alcohol)→HF₂⁻+AH⁺ [Reaction Scheme 4]

SiO₂(s)+2HF₂⁻+2AH⁺→H₂SiF₆+2H₂O+3A [Reaction Scheme 5]

H₂SiF₆→SiF₄(g)+2HF(g) [Reaction Scheme 6]

As described above, isopropyl alcohol (IPA) (C₃H₇OH) added to hydrogen fluoride (HF) may generate HF₂⁻ ion to further facilitate a chemical reaction with a silicon oxide film and may increase wettability of hydrogen fluoride (HF) to easily penetrate into a fine pattern and, thus, etching may be smoothly performed.

In addition, hydrogen fluoride (HF) is re-dissolved in water vapor (H₂O) generated in the chemical reaction and, thus, hydrogen fluoride (HF) includes H⁺, F⁻, and HF₂⁻ ions and non-dissociated hydrogen fluoride (HF) molecules to enable etching to continuously proceed.

As described above, the selective etching method of the silicon oxide film using the low temperature process according to the present invention has technical characteristics of applying a process condition to a process of high pressure and low temperature below zero compared with the prior art and, thus, an experiment for setting an optimum condition is performed through an experiment with respect to process pressure and process temperature.

Hereinafter, an optimum process condition for selective etching of a silicon oxide film using a low temperature process according to the present invention is described through a result of the experiment.

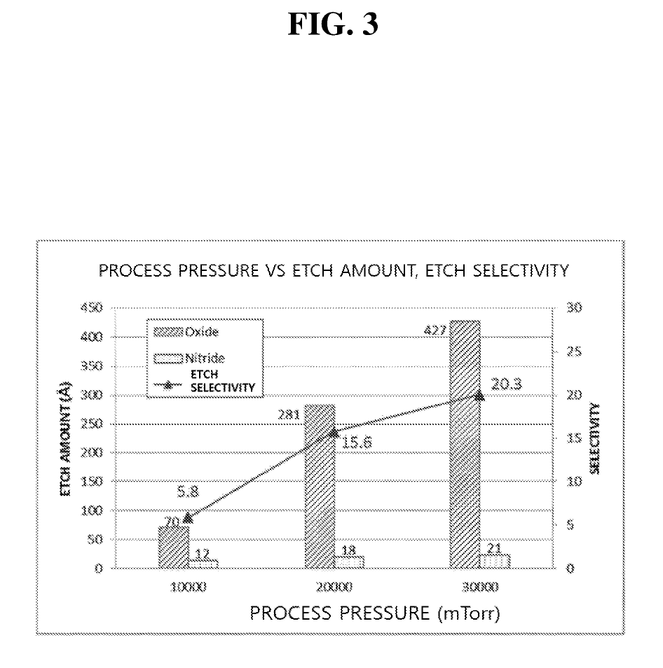

FIG. 3 is a graph showing an etching amount and etch selectivity depending on process pressure in a selective etching method of a silicon oxide film using a low temperature process according to the present invention and, here, temperature of the substrate support 4 is 10° C., a flow rate of HF/IPA is 2000/250 sccm, and an etching time is 60 seconds.

In this case, it may be seen that, as process pressure is increased to 30 Torr from 10 Torr, an etching amount of a silicon oxide film is remarkably increased to 427 Å from 70 Å and, on the other hand, an etching amount of a silicon nitride film is slightly increased to 21 Å from 12 Å.

Accordingly, etch selectivity of a silicon oxide film and a silicon nitride film is largely increased to 20:1 from about 6:1 and, thus, it may be seen that, when process pressure is increased, an etching amount and etch selectivity of the silicon oxide film is increased.

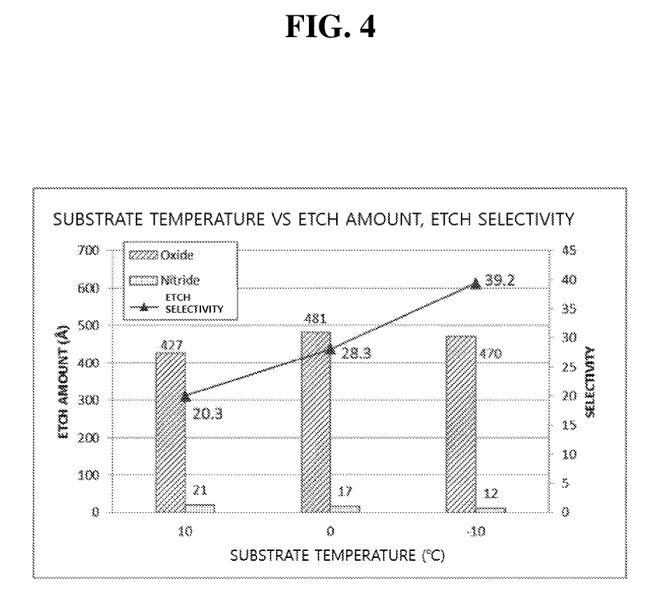

FIG. 4 is a graph showing an etching amount and etch selectivity depending on substrate temperature in a selective etching method of a silicon oxide film using a low temperature process according to the present invention and, here, process pressure is 30 Torr, a flow rate of HF/IPA is 2000/250 sccm, and an etching time is 60 seconds.

In this case, it may be seen that, as substrate temperature is lowered to 10° C. below zero from 10° C., an etching amount of a silicon oxide film is increased to 470 Å from 427 Å by a small degree, but an etching amount of a silicon nitride film is rather reduced to 12 Å from 21 Å and, thus, etch selectivity is increased twice to 40:1 from about 20:1.

It may be determined that this result is based on the fact that water vapor (H₂O) that condenses on a surface of a silicon oxide film along with reduction in process temperature and hydrogen fluoride (HF) react with each other and a fraction of a HF₂⁻ ion that is a main etching component of the silicon oxide film is increased to relatively and further increase an etching amount of the silicon oxide film than the silicon nitride film.

That is, it may be seen that a chemisorbed layer is formed on a surface of the silicon oxide film in a low temperature process and, as chemical reaction at the condensed layer becomes intense, an etching amount of the silicon oxide film is also increased.

As a result, as seen from the experimental results of FIGS. 3 and 4, when process pressure is increased and process temperature are lowered, etch selectivity of the silicon oxide film and the silicon nitride film is remarkably increased.

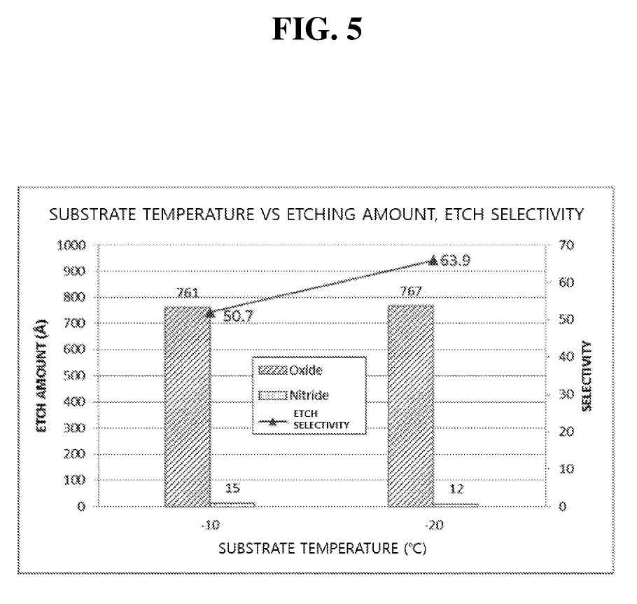

FIG. 5 is a graph for evaluation on a tendency of an etching amount and etch selectivity when substrate temperature is maintained at further low temperature in a selective etching method of a silicon oxide film using a low temperature process according to the present invention.

That is, according to the result of FIGS. 3 and 4, a process condition is reset, process pressure is further increased to 100 Torr and a flow rate of hydrogen fluoride (HF) is slightly increased with a flow rate of HF/IPA of 2500/250 sccm and, then, etching is performed for 60 seconds and, here, substrate temperature may be further lowered to verify reproducibility of the aforementioned experimental result.

As a result, it may be seen that, when substrate temperature is 10° C. below zero, etch selectivity is increased to a level of 50:1 compared with FIG. 4 an, when substrate temperature is further lowered to 20° C. below zero, etch selectivity is further increased to a level of 64:1 and, thus, when process temperature is further lowered, a tendency of etching characteristics are also maintained.

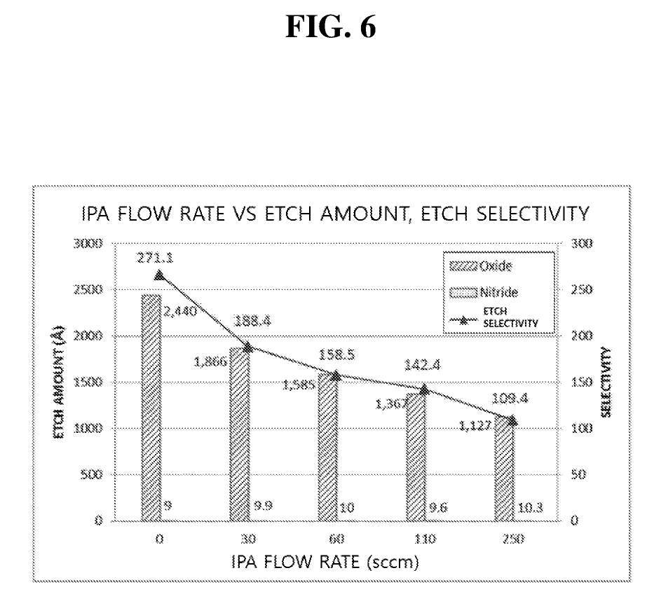

FIG. 6 is a graph showing an etching amount and etch selectivity depending on a flow rate of IAP in a selective etching method of a silicon oxide film using a low temperature process according to the present invention.

That is, FIG. 6 shows an etching amount and etch selectivity along with reduction in a flow rate of added IPA in a state in which process pressure is gradually increased to 100 Torr from 30 Torr, substrate temperature is gradually lowered to 20° C. below zero from 10° C. below zero and, then, hydrogen fluoride (HF) with a flow rate of hydrogen fluoride (HF) is supplied with 2500 sccm.

As a result, it may be seen that, when a flow rate of IPA is supplied with 250 sccm, etch selectivity has a high value of 100:1 but, an etching amount and etch selectivity are further increased along with reduction in a flow rate of IPA and, thus, when IPA is not lastly added and only hydrogen fluoride (HF) is supplied, remarkably high etch selectivity of about 270:1 is achieved.

### Second Embodiment

In the case of the aforementioned embodiment, the case in which hydrogen fluoride (HF) gas and alcohol gas are used as process gas has been described, but in the case of a selective etching method according to another embodiment of the present invention, only hydrogen fluoride (HF) gas may be used as the process gas.

Hereinafter, an example in which only hydrogen fluoride (HF) is used as etching process gas is described with regard to another embodiment of the present invention. The same etching apparatus 1 as in the aforementioned embodiment may be used and, thus, a repeated description of the etching apparatus 1 is omitted here.

In this case, an etching process may include transferring a substrate with a silicon oxide film and a silicon nitride film formed thereon into a reactor, setting a process condition including process gas for selectively removing a silicon oxide film with respect to the silicon nitride film, process pressure, and process temperature, and supplying only hydrogen fluoride (HF) with a predetermined flow rate or greater as the process gas onto the substrate to selectively etch the silicon oxide film with respect to the silicon nitride film. According to the present embodiment, the process condition is similar to the aforementioned embodiment. That is, according to the present embodiment, the process temperature may be maintained at 0° C. to 30° C. below zero and, in detail, 10° C. below zero to 30° C. below zero and the process pressure may be maintained at 30 to 200 Torr and, in detail, 50 to 150 Torr.

Hereinafter, a reaction mechanism in an etching method of a silicon oxide film according to the present embodiment is described.

When hydrogen fluoride (HF) has low concentration, hydrogen fluoride (HF) may react with water (H₂O) according to Reaction Scheme 7 below to generate an F-ion due to weak acidity and, when hydrogen fluoride (HF) has high concentration, hydrogen fluoride (HF) may be dissociated to generate a HF₂-ion according to Reaction Scheme 8 below due to strong acidity.

The generated F-ion and HF₂-ion may function as main components for etching a silicon oxide film to maintain an etching reaction.

HF+H₂O↔H₃O++F− [Reaction Scheme 7]

3HF↔H₂F++HF₂− [Reaction Scheme 8]

To allow hydrogen fluoride (HF) and the silicon oxide film to react with each other, first, silanol (Si—O—H) bond may be formed on a surface of the silicon oxide film due to acidity of hydrogen fluoride (HF) and hydrogen fluoride (HF) that adsorbs onto the silicon oxide film may generate water (H₂O) along with SiF₄ or H₂SiF₆ according to Reaction Scheme 9 or 10 below.

SiO₂+4HF→SiF₄(g)+2H₂O [Reaction Scheme 9]

SiO₂+6HF→H₂SiF₆+2H₂O [Reaction Scheme 10]

H₂SiF₆→SiF₄(g)+2HF(g) [Reaction Scheme 11]

In addition, hydrogen fluoride (HF) is re-dissolved by the water (H₂O) generated by the reaction and, thus, hydrogen fluoride (HF) includes H+, F−, and HF₂− ions and non-dissociated hydrogen fluoride (HF) molecules to enable etching to continuously proceed.

SiF₄ generated via the reaction may be directly discharged due to volatility but H₂SiF₆ may be re-dissociated according to Reaction Scheme 11 above and may be discharged as SiF₄ to reproduce hydrogen fluoride (HF).

Water (H₂O) that adsorbs onto a surface of a thin film functions as a catalyst and, thus, etching of a silicon oxide film using hydrogen fluoride (HF) gas may be affected by whether water (H₂O) is present.

That is, content of water (H₂O) in a thin film is changed depending on a difference in hygroscopic property such as a process of forming a silicon oxide film, density of the silicon oxide film, and whether the silicon oxide film is doped, and an exposure degree of a moisture environment and, thus, etching characteristics may also be changed.

Accordingly, an etching process of a silicon oxide film using hydrogen fluoride (HF) gas may have a difference in characteristics depending on inherent water content in the silicon oxide film and, for example, in the case of a silicon oxide film with high inherent water content among heterogeneous silicon oxide films, initiation and acceleration of reaction are rapidly performed and an overall etching amount may be increased.

As a result, water (H₂O) is barely supplied in an initial stage of a reaction in etching of a silicon oxide film using hydrogen fluoride (HF) gas and, thus, water (H₂O) generated via a reaction with inherent water content in the silicon oxide film before the reaction proceeds may play an important role to perform a process.

Accordingly, the following phenomenon occurs, that is, after water (H₂O) is generated via a reaction, the reaction is accelerated due to catalysis of water (H₂O) but, before water (H₂O) is generated, inherent water in a silicon oxide film is used as described above, initiation of the reaction is delayed.

That is, water (H₂O) is insufficient in an initial stage of a reaction and, thus, reaction rate is low and, after a reaction for generating water (H₂O) proceeds by a threshold value or greater, the reaction is accelerated using the generated water (H₂O).

In addition, hydrogen fluoride (HF) re-produced according to Reaction Scheme 11 above functions as a supply source of hydrogen fluoride (HF), but to rapidly and continuously perform a reaction, only the re-produced HF is insufficient and a flow rate of hydrogen fluoride (HF) supplied as process gas to a reactor needs to be sufficient.

As described above, in the selective etching method of a silicon oxide film according to the present invention, hydrogen fluoride (HF) gas may be used as process gas, the process condition may be maintained at high pressure of 30 to 200 Torr, in detail, 50 to 150 Torr and low temperature below zero and a flow rate of hydrogen fluoride (HF) to enhance the etching amount and etch selectivity of the silicon oxide film.

That is, as the process temperature is maintained at low temperature, water (H₂O) may be increasingly condensed on a surface of the silicon oxide film and a fraction of an F− or HF₂− ion that is a main component for etching the silicon oxide film may be increased via a reaction between the condensed water (H₂O) and hydrogen fluoride (HF).

As such, an etching amount of the silicon oxide film is increased, but an etching amount of the silicon nitride film is relatively reduced and, thus, high etch selectivity equal to or greater than 200:1 may be achieved.

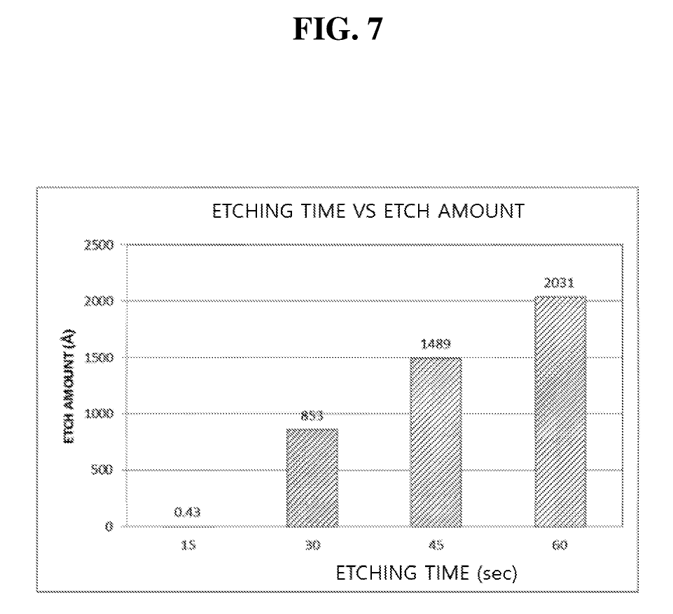

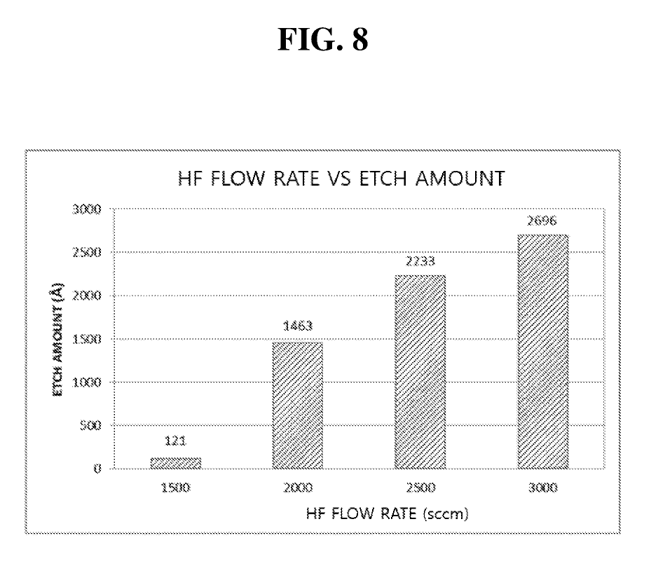

When only hydrogen fluoride (HF) is used under the process condition according to the present embodiment, evaluation on etching characteristics is performed and FIGS. 7 and 8 show a result thereof and are graphs showing a change in an etching amount depending on an etching time and a flow rate of hydrogen fluoride (HF).

As seen from FIG. 7, when an etching time is 15 seconds, an etching amount of the silicon oxide film is a negligible level and, on the other hand, when an etching time is 30 seconds or more, a sufficient etching amount is ensured.

As described above, this may be analyzed to be caused from the following phenomenon, that is, in the case of the etching process of a silicon oxide film using hydrogen fluoride (HF) gas without supplying water (H₂O), only inherent water (H₂O) in the silicon oxide film is used before water (H₂O) is generated via a reaction and, thus, initiation of the reaction is delayed.

As seen from FIG. 8, when a flow rate of hydrogen fluoride (HF) gas is 1500 sccm, an etching amount is low and, on the other hand, when hydrogen fluoride (HF) gas is supplied with 2000 sccm or greater, that is, 2000 sccm to 3000 sccm, etching is smoothly performed.

As described above, this may also be analyzed to be caused from the following phenomenon, that is, it may be difficult in rapidly and continuously performing a reaction only using the hydrogen fluoride (HF) gas re-produced according to Reaction Scheme 11 above and, thus, when a flow rate of hydrogen fluoride (HF) gas supplied into a reactor is sufficient, an etching amount is increased.

As such, as seen from the results of FIGS. 7 and 8, as an etching time is increased and a supplying rate of hydrogen fluoride (HF) gas is increased, an etching amount is increased.

As seen from the aforementioned result, along with reduction in temperature, loss of a silicon nitride film may be reduced and, when temperature is lowered to temperature less than 30° C. below zero, an etching amount of a silicon oxide film is remarkably reduced to lastly reduce etch selectivity.

Accordingly, in the selective etching method of a silicon oxide film using a low temperature process according present invention, process temperature may be maintained at 0° C. to 30° C. below zero and, in detail, 10° C. to 30° C. below zero.

It may be seen that, when alcohol gas is used as process gas, as a flow rate of IPA in a flow rate ratio of HF/IPA is increased, etch selectivity has a tendency of being reduced. Accordingly, a flow rate of HF may be equal to or greater than 2500 sccm and a flow rate ratio of HF/IPA may be adjusted to be equal to or greater than 5:1 and, in detail, to be equal to or greater than 10:1 and, thus, a stable etching process may be performed.

In addition, when pressure is increased, an etching amount and etch selectivity have a tendency of being increased but, even if the pressure is further increased and reaches 200 Torr, an etching amount and etch selectivity are not largely changed.

When pressure is excessively increased, there is a problem in that a burden to install and maintain facilities for maintaining a high-pressure state is generated and a time consumed to increase and reduce pressure is increased when many substrates are process, thereby reducing throughput.

Accordingly, in the selective etching method of a silicon oxide film using a low temperature process according present invention, process pressure may be maintained at 30 to 200 Torr, and, in detail, 50 to 150 Torr.

It may be seen that, the above process condition is maintained and, thus, the selective etching method of a silicon oxide film using a low temperature process according present invention may stably achieve etch selectivity equal to or greater than 100:1 of a silicon oxide film, which is not embodied in the prior art.

Accordingly, the selective etching method of a silicon oxide film using a low temperature process according present invention may be applicable to various fields such as micro-electro-mechanical systems (MEMS) or a semiconductor, using an etching process of high selectivity of a silicon oxide film and a silicon nitride film, which is desperately needed along with recent miniaturization of patterns.

While the present invention has been particularly shown and described with reference to exemplary embodiments thereof, it will be understood by those of ordinary skill in the art that various changes in form and details may be made therein without departing from the spirit and scope of the present invention as defined by the following claims.

In the selective etching method of a silicon oxide film according to the present invention, an etching process may be performed at high pressure and a low temperature condition of temperature below zero differently from the prior art, and, thus, etch selectivity of a silicon oxide film may be remarkably enhanced.

The selective etching method of a silicon oxide film according to the present invention may use a dry etching method of injecting hydrogen fluoride (HF) and alcohol in a gas phase and, thus, a non-volatility reaction product may be originally prevented from being generated and a problem in terms of non-uniform process temperature due to a thermal process may be overcome.

1. A selective etching method of a silicon oxide film, the method comprising:
transferring a substrate with a silicon oxide film and a silicon nitride film formed thereon into a reactor;
setting a process condition including process temperature of the substrate in the range of 0° C. to 30° C. below zero; and
supplying process gas to the reactor under the process condition to selectively etch the silicon oxide film with respect to the silicon nitride film.

2. The method of claim 1, wherein process pressure in the reactor is in the range of 30 to 200 Torr.

3. The method of claim 1, wherein process pressure in the reactor is maintained at 50 to 150 Torr, and
wherein hydrogen fluoride (HF) gas and IPA gas are used as the process gas.

4. The method of claim 3, wherein a flow rate ratio of the hydrogen fluoride (HF) gas and the IPA gas is equal to or greater than 5:1.

5. The method of claim 3, wherein a flow rate ratio of the hydrogen fluoride (HF) gas and the IPA gas is equal to or greater than 10:1.

6. A selective etching method of a silicon oxide film, the method comprising:
transferring a substrate with a silicon oxide film and a silicon nitride film formed thereon into a reactor;
setting a process condition including process gas, process pressure in the reactor, and process temperature of the substrate for selectively removing a silicon oxide film with respect to the silicon nitride film; and
supplying only hydrogen fluoride (HF) as the process gas with a predetermined flow rate or greater onto the substrate to selectively etch the silicon oxide film with respect to the silicon nitride film.

7. The method of claim 6, wherein the flow rate of the hydrogen fluoride (HF) is 2000 to 3000 sccm.

8. The method of claim 6, wherein the process pressure in the reactor is maintained in the range of 50 to 150 Torr and the process temperature is maintained in the range of 10° C. below zero to 30° C. below zero.
